(19) United States
(12) Patent Application Publication
(10) Pub. No.: US 2020/0324370 A1
(43) Pub. Date: Oct. 15, 2020

(54) MULTILAYER SUBSTRATE SHAPING METHOD AND MULTILAYER SUBSTRATE SHAPING APPARATUS

(71) Applicant: KANTATSU CO., LTD., Yaita-shi (JP)

(72) Inventor: Eiji OSHIMA, Yaita-shi (JP)

(21) Appl. No.: 16/665,235

(22) Filed: Oct. 28, 2019

(30) Foreign Application Priority Data
Oct. 26, 2018 (JP) 2018-201382

(51) Int. Cl. B23K 26/082; B23K 26/03; H05K 3/46

(52) U.S. Cl. CPC B23K 26/082; B23K 2101/42; H05K 3/4664; B23K 26/032

(57) ABSTRACT

This invention forms a multilayer substrate by one apparatus. A multilayer substrate forming method includes fixing a substrate on a stage, forming, on the substrate fixed on the stage, a layer of a mixed material obtained by mixing a conductive material and a photo-curing resin, performing exposure by scanning a laser beam according to first circuit pattern data prepared in advance on the layer of the mixed material, washing away the mixed material on the substrate after the exposure in the performing exposure by scanning the laser beam according to the first circuit pattern data, forming a layer of an insulating resin on the substrate after the cleaning in the washing away the mixed material on the substrate after the exposure in the performing exposure by scanning the laser beam according to the first circuit pattern data, performing exposure by scanning a laser beam according to through hole data prepared in advance on the layer of the insulating resin, washing away the insulating resin on the substrate after the exposure in the performing exposure by scanning the laser beam according to the through hole data, forming a layer of the mixed material on the substrate after the cleaning in the washing away the insulating resin, performing exposure by scanning a laser beam according to second circuit pattern data prepared in advance on the layer of the mixed material, and washing away the mixed material on the substrate after the exposure in the performing exposure by scanning the laser beam according to the second circuit pattern data.

### BACKGROUND OF THE INVENTION

### Field of the Invention

The present invention relates to a multilayer substrate forming method and a multilayer substrate forming apparatus.

### Description of the Related Art

In the above technical field, patent literature 1 discloses a technique of manufacturing a multilayer substrate using plating, and further discloses a technique using a mask to manufacture an insulating layer.

[Patent Literature 1] Japanese Patent Laid-Open No. 2011-3567

### SUMMARY OF THE INVENTION

In the technique described in the above literature, however, it is impossible to form a multilayer substrate by one apparatus.

The present invention provides a technique of solving the above-described problem.

One example aspect of the present invention provides a multilayer substrate forming method comprising:

fixing a substrate on a stage;

forming, on the substrate fixed on the stage, a layer of a mixed material obtained by mixing a conductive material and a photo-curing resin;

performing exposure by scanning a laser beam according to first circuit pattern data prepared in advance on the layer of the mixed material;

washing away the mixed material on the substrate after the exposure in the performing exposure by scanning the laser beam according to the first circuit pattern data;

forming a layer of an insulating resin on the substrate after the cleaning in the washing away the mixed material on the substrate after the exposure in the performing exposure by scanning the laser beam according to the first circuit pattern data;

performing exposure by scanning a laser beam according to through hole data prepared in advance on the layer of the insulating resin;

washing away the insulating resin on the substrate after the exposure in the performing exposure by scanning the laser beam according to the through hole data;

forming a layer of the mixed material on the substrate after the cleaning in the washing away the insulating resin;

performing exposure by scanning a laser beam according to second circuit pattern data prepared in advance on the layer of the mixed material; and

washing away the mixed material on the substrate after the exposure in the performing exposure by scanning the laser beam according to the second circuit pattern data.

Another example aspect of the present invention provides a multilayer substrate forming apparatus comprising:

a mixed material layer former that forms, on a substrate, a layer of a mixed material obtained by mixing a conductive material and a photo-curing resin;

an insulating resin layer former that forms a layer of an insulating resin on the substrate;

an exposurer that performs exposure;

a cleaner that performs cleaning; and

a controller that controls the mixed material layer former, the insulating resin layer former, the exposure, and the cleaner,

wherein the controller controls to perform processing of forming the layer of the mixed material by the mixed material layer former, processing of performing exposure by scanning a laser beam according to first circuit pattern data by the exposurer, processing of cleaning the mixed material after the exposure by the cleaner, processing of forming the layer of the insulating resin by the insulating resin layer former, processing of performing exposure by scanning a laser beam according to through hole data by the exposurer, and processing of cleaning the insulating resin after the exposure by the cleaner at least once, and then

perform processing of forming the layer of the mixed material by the mixed material layer former, processing of performing exposure by scanning a laser beam according to second circuit pattern data by the exposurer, and processing of cleaning the mixed material after the exposure by the cleaner.

According to the present invention, it is possible to form a multilayer substrate by one apparatus.

### BRIEF DESCRIPTION OF THE DRAWINGS

FIG. 1 is a flowchart showing a multilayer substrate forming method according to the first example embodiment of the present invention;

FIG. 2 is a block diagram showing the functional arrangement of a multilayer substrate forming apparatus according to the second example embodiment of the present invention;

FIG. 3A is a view showing the arrangement of the multilayer substrate forming apparatus according to the second example embodiment of the present invention;

FIG. 3B is a view showing the arrangement of an exposurer of the multilayer substrate forming apparatus according to the second example embodiment of the present invention;

FIG. 4A is a view for explaining an example of circuit pattern formation (first layer) by the multilayer substrate forming apparatus according to the second example embodiment of the present invention;

FIG. 4B is a view for explaining an example of insulating resin layer formation by the multilayer substrate forming apparatus according to the second example embodiment of the present invention;

FIG. 4C is a view for explaining an example of circuit pattern formation (second layer) by the multilayer substrate forming apparatus according to the second example embodiment of the present invention;

FIG. 4D is a view for explaining an example of chip mount after multilayer substrate formation by the multilayer substrate forming apparatus according to the second example embodiment of the present invention;

FIG. 5 is a flowchart showing a processing procedure by the multilayer substrate forming apparatus according to the second example embodiment of the present invention;

FIG. 6 is a block diagram showing the functional arrangement of a multilayer substrate forming apparatus according to the third example embodiment of the present invention;

FIG. 7 is a view showing the arrangement of the multilayer substrate forming apparatus according to the third example embodiment of the present invention; and

FIG. 8 is a view showing the arrangement of a multilayer substrate forming apparatus according to the fourth example embodiment of the present invention.

### DESCRIPTION OF THE EXAMPLE EMBODIMENTS

Example embodiments of the present invention will now be described in detail with reference to the drawings. It should be noted that the relative arrangement of the components, the numerical expressions and numerical values set forth in these example embodiments do not limit the scope of the present invention unless it is specifically stated otherwise.

### First Example Embodiment

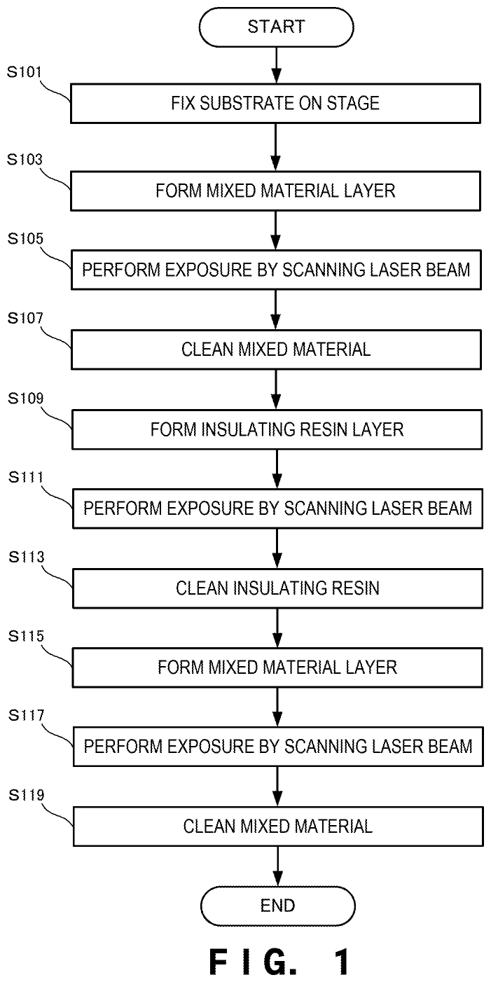

A multilayer substrate forming method according to the first example embodiment of the present invention will be described with reference to FIG. 1. FIG. 1 is a flowchart showing the multilayer substrate forming method according to this example embodiment. This flowchart is executed by the CPU (Central Processing Unit) of a multilayer substrate forming apparatus using a RAM (Random Access Memory), and the functional components of the multilayer substrate forming apparatus are implemented.

In step S101, the multilayer substrate forming apparatus fixes a substrate on a stage. In step S103, the multilayer substrate forming apparatus forms, on the substrate fixed on the stage, a layer of a mixed material obtained by mixing a conductive material and a photo-curing resin. In step S105, the multilayer substrate forming apparatus performs exposure by scanning a laser beam according to first circuit pattern data prepared in advance on the layer of the mixed material. In step S107, the multilayer substrate forming apparatus washes away the mixed material on the substrate after the exposure in step S105.

In step S109, the multilayer substrate forming apparatus forms a layer of an insulating resin on the substrate after the cleaning in step S107. In step S111, the multilayer substrate forming apparatus performs exposure by scanning a laser beam according to through hole data prepared in advance on the layer of the insulating resin. In step S113, the multilayer substrate forming apparatus washes away the insulating resin on the substrate after the exposure in step S111.

In step S115, the multilayer substrate forming apparatus forms a layer of a mixed material on the substrate after the cleaning in step S113. In step S117, the multilayer substrate forming apparatus performs exposure by scanning a laser beam according to second circuit pattern data prepared in advance on the layer of the mixed material. In step S119, the multilayer substrate forming apparatus washes away the mixed material on the substrate after the exposure in step S117.

According to this example embodiment, it is possible to form a multilayer substrate by one apparatus.

### Second Example Embodiment

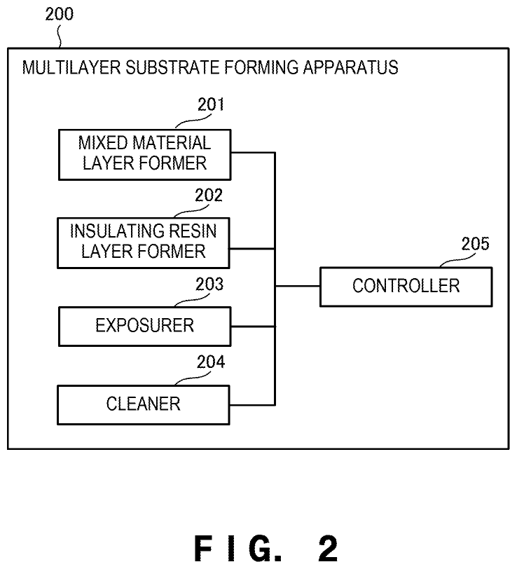

A multilayer substrate forming apparatus according to the second example embodiment of the present invention will be described next with reference to FIGS. 2 to 5. FIG. 2 is a block diagram showing the functional arrangement of the multilayer substrate forming apparatus according to this example embodiment. The multilayer substrate forming apparatus 200 includes a mixed material layer former 201, an insulating resin layer former 202 an exposurer 203, a cleaner 204, and a controller 205.

The mixed material layer former 201 forms, on a substrate, a layer of a mixed material obtained by mixing a conductive material and a photo-curing resin. The insulating resin layer former 202 forms a layer of an insulating resin on the substrate. The exposurer 203 performs exposure. The cleaner 204 performs cleaning. The controller 205 controls the mixed material layer former 201, the insulating resin layer former 202, the exposurer 203, and the cleaner 204.

The controller 205 controls to perform the processing of forming the layer of the mixed material by the mixed material layer former 201, the processing of performing exposure by scanning the laser beam according to the circuit pattern data of the first layer by the exposurer 203, the processing of cleaning the mixed material after the exposure by the cleaner 204, the processing of forming the layer of the insulating resin by the insulating resin layer former 202, the processing of performing exposure by scanning the laser beam according to the through hole data by the exposurer 203, and the processing of cleaning the insulating resin after the exposure by the cleaner 204 at least once, and then perform the processing of forming the layer of the mixed material by the mixed material layer former 201, the processing of performing exposure by scanning the laser beam according to the circuit pattern data of the second layer by the exposurer 203, and the processing of cleaning the mixed material after the exposure by the cleaner 204. In this way, the multilayer substrate forming apparatus 200 executes the above-described processes and forms a multilayer substrate by one apparatus.

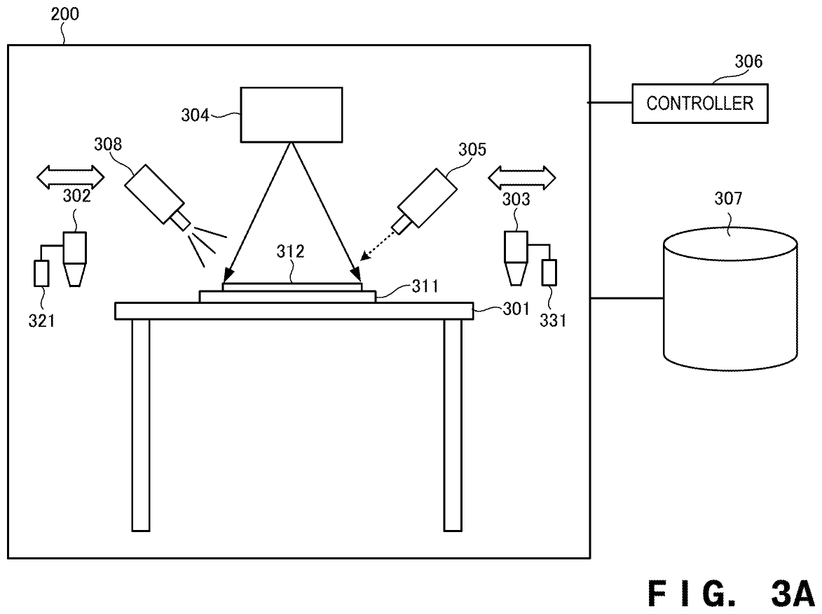

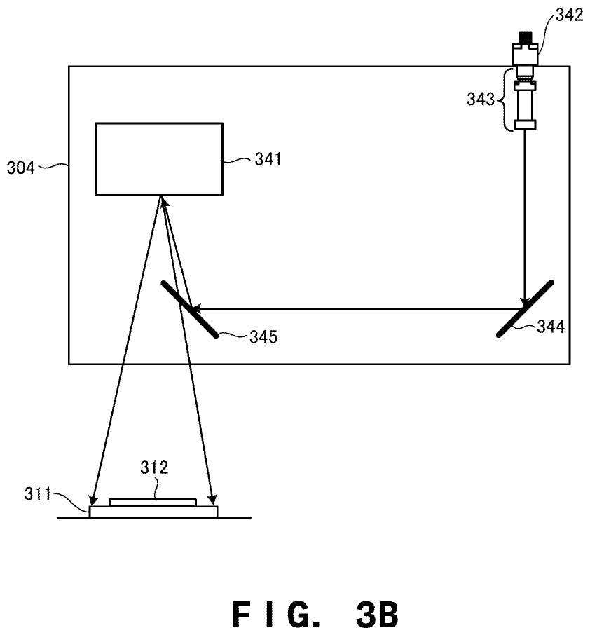

FIG. 3A is a view showing the arrangement of the multilayer substrate forming apparatus according to this example embodiment. The multilayer substrate forming apparatus 200 includes a stage 301, a mixed material layer former 302, an insulating resin layer former 303, an exposurer 304, a cleaner 305, a controller 306, a storage unit 307, and a dryer 308.

A substrate 311 is fixed on the stage 301. Any fixing method can be used as long as it makes the substrate 311 unmovable on the stage 301. A multilayer circuit 312 including a plurality of circuit pattern layers is formed on the substrate 311. The substrate 311 is, for example, a liquid crystal polymer resin substrate, a polyimide resin substrate, a glass substrate, a ceramic substrate, or a glass epoxy substrate, but is not limited to these.

The mixed material layer former 302 forms, on the substrate 311 fixed on the stage 301, a layer of a mixed material obtained by mixing a conductive material and a photo-curing resin. The formation of the layer of the mixed material is performed by, for example, applying the mixed material from the mixed material layer former 302 onto the substrate 311 and leveling the applied mixed material by a leveler 321 to a desired thickness. The thickness of the mixed material layer formed by the mixed material layer former 302 is 10 μm to 15 μm, but is not limited to this.

The leveler 321 is a rod-shaped elongated member. Note that the mixed material is a paste-like material to facilitate application. The mixed material layer former 302 is installed to be movable on the stage 301. The leveler 321 is installed to move following the movement of the mixed material layer former 302.

The conductive material is, for example, silver, gold, copper, platinum, lead, zinc, tin, iron, aluminum, palladium, carbon, or the like, but is not limited to these. The photo-curing resin is, for example, a UV-curing resin such as an acrylic resin (polymer acrylate), an urethane resin (urethane acrylate), a vinyl ester resin, or a polyester-alkyd resin (epoxy acrylate). However, the photo-curing resin is not limited to these as long as it is a resin cured by light beam irradiation.

The insulating resin layer former 303 forms a layer of an insulating resin on the substrate 311. The formation of the layer of the insulating resin is performed by, for example, applying the insulating resin from the insulating resin layer former 303 onto the substrate 311 and leveling the applied insulating resin by a leveler 331 to a desired thickness. The thickness of the insulating resin formed by the insulating resin layer former 303 is 8 μm to 12 μm, but is not limited to this.

The leveler 331 is a rod-shaped elongated member. Note that the insulating resin has such a hardness that facilitates application. The insulating resin layer former 303 is installed to be movable on the stage. The leveler 331 is installed to move following the movement of the insulating resin layer former 303.

A laser beam emitted from the exposurer 304 is a laser beam having a wavelength of about 405 nm, but is not limited to this. The laser beam may be a light beam having a wavelength of, for example, 200 nm to 400 nm, but is not limited to this.

The cleaner 305 washes away and cleans the mixed material after the exposure. Similarly, the cleaner 305 washes away and cleans the insulating resin after the exposure. The cleaner 305 is a nozzle-shaped member, and performs cleaning by jetting a cleaning agent from the nozzle to the substrate 311. When jetting the cleaning agent, the cleaner 305 may apply a pressure to the cleaning agent to jet it. This makes it possible to reliably wash away the mixed material and the insulating resin, which should be removed. The cleaning agent is, for example, a volatile cleaning agent, but is not limited to this.

The controller 306 controls the mixed material layer former 302, the insulating resin layer former 303, the exposurer 304, the cleaner 305, and the dryer 308. The controller 306 controls the mixed material layer former 302 to form the mixed material layer on the substrate 311.

Then, the controller 306 controls the exposurer 304 to perform exposure by scanning a laser beam according to a circuit pattern prepared in advance on the mixed material layer. When the exposure of the mixed material layer is ended, the controller 306 controls the cleaner 305 to wash away the mixed material on the substrate 311. For example, the circuit pattern of the first layer is thus formed.

Next, the controller 306 controls the insulating resin layer former 303 to form the insulating resin layer on the substrate 311. Then, the controller 306 controls the exposurer 304 to perform exposure by scanning a laser beam according to through hole data prepared in advance on the insulating resin layer. When the exposure of the insulating resin layer is ended, the controller 306 controls the cleaner 305 to wash away the insulating resin on the substrate 311. The insulating resin layer of the first layer provided with through holes is thus formed.

Then, the controller 306 controls the mixed material layer former 302, the exposurer 304, and the cleaner 305 to repeat a procedure similar to that of the formation of the circuit pattern of the first layer, thereby forming the circuit pattern of the second layer.

The storage unit 307 stores circuit pattern data used when exposing the mixed material layer. The circuit pattern data are stored in accordance with the number of mixed material layers to be formed. Similarly, the storage unit 307 stores through hole data used when exposing the insulating resin layer. The through hole data are stored in accordance with the number of insulating resin layers to be formed.

The dryer 308 blows air or warm air to the substrate 311. This can quickly dry the cleaning agent after cleaning by the cleaner 305.

FIG. 3B is a view showing the arrangement of the exposurer of the multilayer substrate forming apparatus according to this example embodiment. The exposurer 304 includes a two-dimensional MEMS (Micro Electro Mechanical System) mirror 341. The two-dimensional MEMS mirror 341 is an electromechanical mirror.

A laser source 342 is the source of a laser beam. The laser beam emitted by the laser source 342 is guided to a condenser 343. The condenser 343 includes a condenser lens, a collimator lens, and the like. In addition, the laser source 342 is a semiconductor LD (Laser Diode), and is a laser beam oscillation element that emits (oscillates) a visible laser beam or the like. The laser beam that has entered the condenser 343 is, for example, condensed by the condenser lens and converted into a parallel beam by the collimator lens, and then exits.

Here, the laser beam emitted by the laser source 342 is reflected by mirrors 344 and 345 and reaches the two-dimensional MEMS mirror 341. The mirror 345 is arranged on the bottom portion (bottom surface of the exposurer 304. The mirror 344 reflects the reflected light of the laser beam from the laser source 342 downward to the mirror 345 arranged on bottom surface. The mirror 345 reflects the laser beam from the mirror 344 upward to the two-dimensional MEMS mirror 341 arranged above the mirror 345. The two-dimensional MEMS mirror 341 scans the reflected light from the mirror 345 in a two-dimensional direction to irradiate. Note that an example in which one laser source is used has been described above. However, a plurality of laser sources may be used. If a plurality of light sources are used, a plurality of laser beams of different wavelengths can selectively be used. For this reason, laser beams of different wavelengths can be used in a case of exposing the mixed material layer and a case of exposing the insulating resin layer.

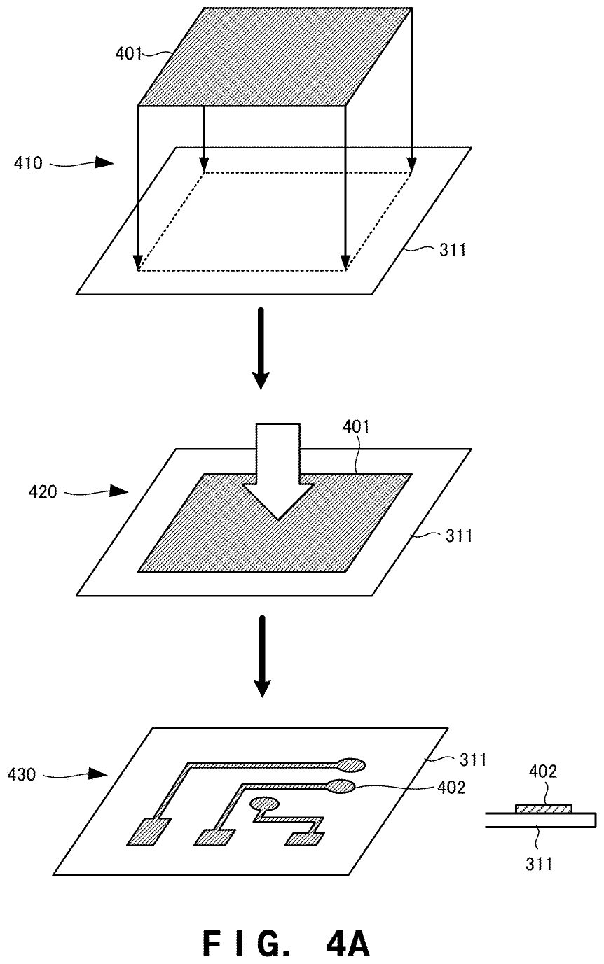

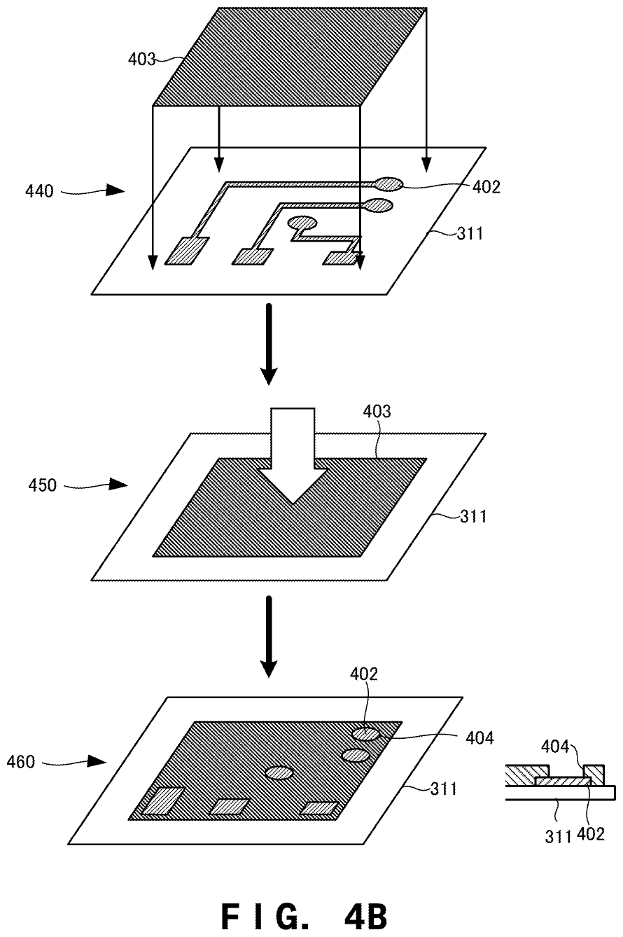

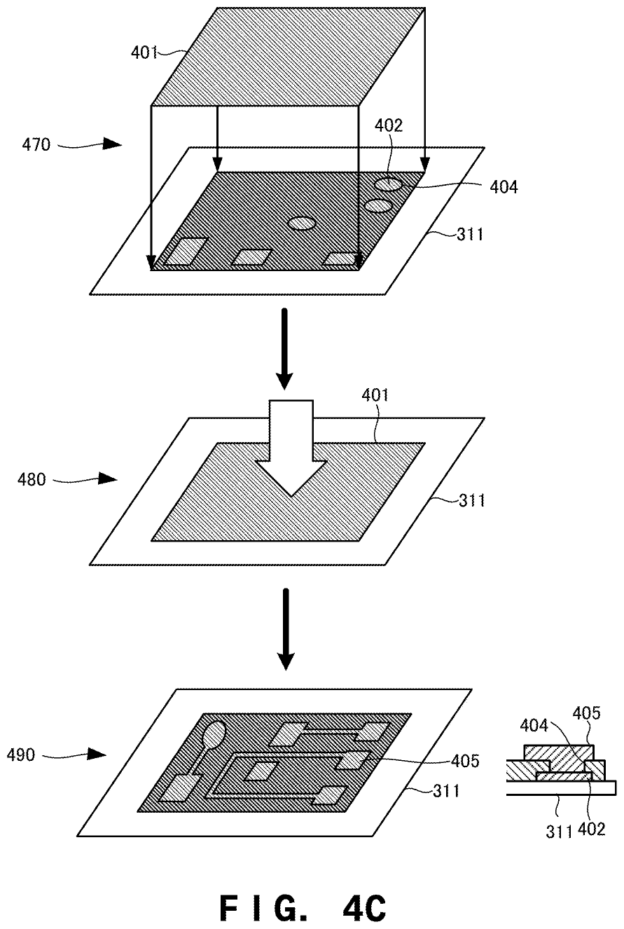

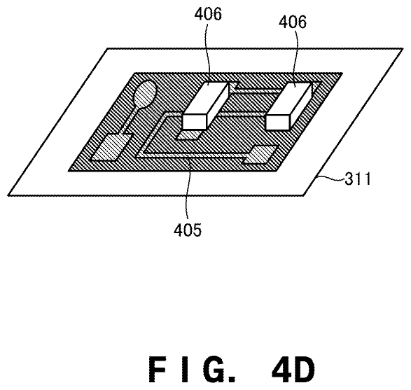

FIG. 4A is a view for explaining an example of circuit pattern formation (first layer) by the multilayer substrate forming apparatus according to this example embodiment. First, a mixed material 401 is applied onto the substrate 311 (410). Next, the applied mixed material 401 is irradiated with a laser beam and exposed (420). The mixed material 401 after the exposure is cleaned (430). A circuit pattern 402 (for example, the first layer) is thus formed on the substrate 311. Note that a drying process may be performed after the cleaning.

FIG. 4B is a view for explaining an example of insulating resin layer formation by the multilayer substrate forming apparatus according to this example embodiment. First, an insulating resin 403 is applied onto the mixed material layer with the circuit pattern 402 (440). Next, the applied insulating resin 403 is irradiated with a laser beam and exposed (450). The insulating resin 403 after the exposure is cleaned (460). An insulating resin layer (resist layer) with through holes 404 is thus formed. Here, the through hole 404 is a hole used to connect the upper and lower layers and is called a through hole or a via hole. In addition, the shape of the through hole is not limited to a circular shape, and any shape such as an elliptical shape, a rectangular shape, or a polygonal shape can be used. The size of the through hole is a size according to the thickness of the mixed material layer and the thickness of the insulating resin layer. Note that a drying process may be performed after the cleaning. In addition, no photomask is needed to form the insulating resin layer.

FIG. 4C is a view for explaining an example of circuit pattern formation (second layer) by the multilayer substrate forming apparatus according to this example embodiment. First, the mixed material 401 is applied onto the insulating resin layer with the through holes 404 (470). Next, the applied mixed material 401 is irradiated with a laser beam and exposed (480). The mixed material 401 after the exposure is cleaned (490). A circuit pattern 405 (second layer) is thus formed on the substrate 311. Note that a drying process may be performed after the cleaning.

By appropriately repeating the above-described operation, a multilayer substrate formed by alternately stacking the mixed material layer and the insulating resin layer is obtained. Additionally, during the above-described operation, the substrate 311 is not moved and is kept fixed on the stage 301. Note that the size of the substrate 311 is not limited. According to the multilayer substrate forming apparatus 200, for example, even if the substrate 311 having a size of 1.6 mm×0.8 mm is used, a multilayer substrate can be formed. In addition, a multilayer substrate having such a size that enables implementation in a BGA (Ball Grid Array) package can also be formed.

FIG. 4D is a view for explaining an example of chip mount after multilayer substrate formation by the multilayer substrate forming apparatus according to this example embodiment. A cream solder is applied to the multilayer substrate obtained in accordance with the procedure shown in FIGS. 4A to 4C. A chip 406 is placed on it and soldered to the multilayer substrate by a reflow method. The chip 406 can thus be mounted on the multilayer substrate.

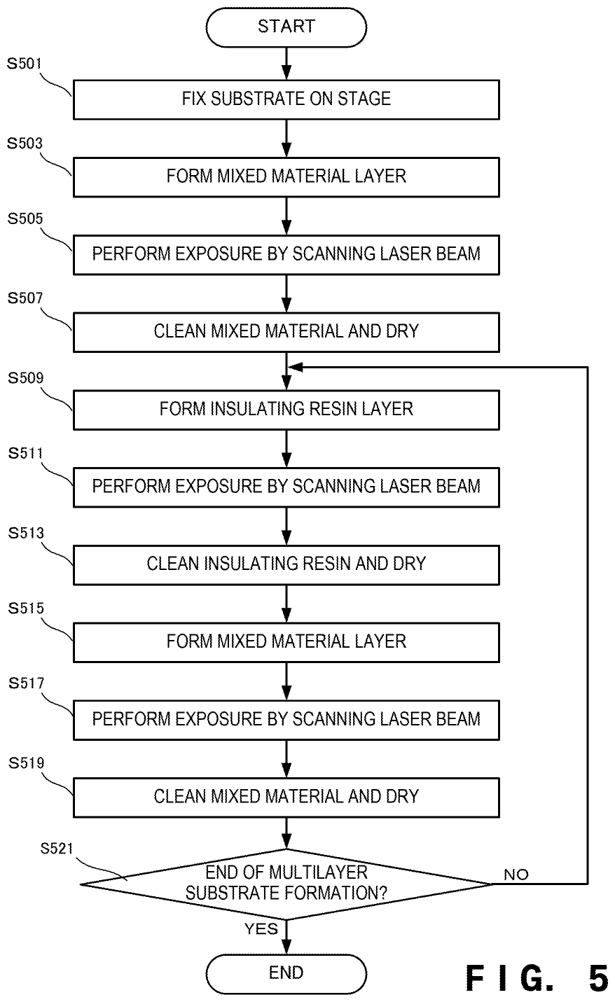

FIG. 5 is a flowchart showing a processing procedure by the multilayer substrate forming apparatus according to this example embodiment. In step S501, the multilayer substrate forming apparatus 200 fixes the substrate 311 on the stage 301. In step S503, the multilayer substrate forming apparatus 200 forms a layer of a mixed material obtained by mixing a conductive material and a photo-curing resin on the substrate 311. In step S505, the multilayer substrate forming apparatus 200 performs exposure by scanning a laser beam according to circuit pattern data (first layer) prepared in advance. In step S507, the multilayer substrate forming apparatus 200 washes away and cleans the mixed material after the exposure, and blows a wind for drying to dry the substrate 311 after the cleaning. The circuit pattern (first layer) is thus formed.

In step S509, the multilayer substrate forming apparatus 200 forms a layer of an insulating resin on the formed circuit pattern. In step S511, the multilayer substrate forming apparatus 200 performs exposure by scanning a laser beam according to through hole data prepared in advance. In step S513, the multilayer substrate forming apparatus 200 washes away and cleans the insulating resin after the exposure, and blows a wind for drying to dry the substrate 311 after the cleaning. The insulating resin layer (resist layer) with through holes is thus formed.

In step S515, to form the circuit pattern of the second layer, the multilayer substrate forming apparatus 200 forms a mixed material layer on the mixed material layer with the circuit pattern and the insulating resin layer with the through holes. In step S517, the multilayer substrate forming apparatus 200 performs exposure by scanning a laser beam according to circuit pattern data (second layer) prepared in advance. In step S519, the multilayer substrate forming apparatus 200 washes away and cleans the mixed material after the exposure, and blows a wind for drying to dry the substrate 311 after the cleaning.

In step S521, the multilayer substrate forming apparatus 200 determines whether the multilayer substrate formation is ended. Upon determining that the multilayer substrate formation is not ended (NO in step S521), the multilayer substrate forming apparatus 200 repeats the steps from step S503. Upon determining that the multilayer substrate formation is ended (YES in step S521), the multilayer substrate forming apparatus 200 ends the processing.

According to this example embodiment, since the multilayer substrate can be formed by one apparatus, the multilayer substrate can be formed quickly and easily. In addition, a photomask used to form an insulating layer is unnecessary, the multilayer substrate can be formed simply and quickly.

### Third Example Embodiment

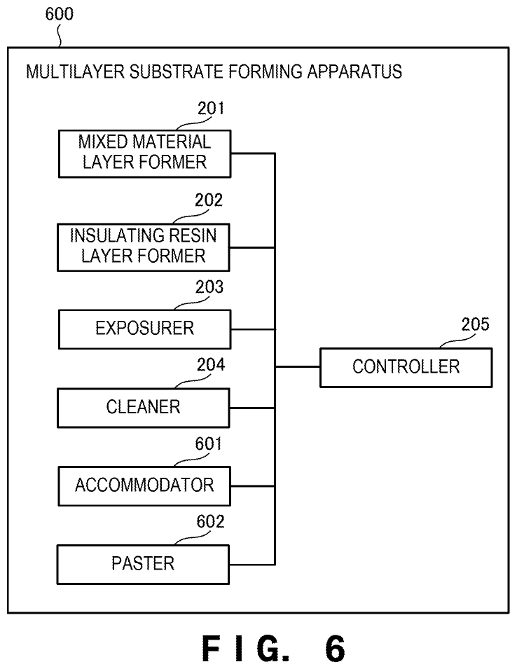

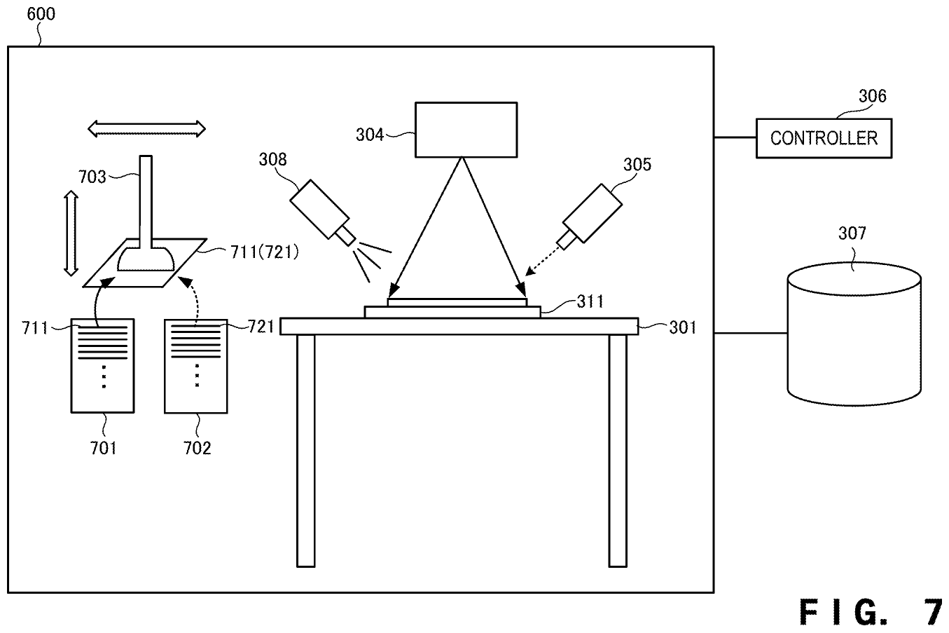

A multilayer substrate forming apparatus according to the third example embodiment of the present invention will be described next with reference to FIGS. 6 and 7. FIG. 6 is a block diagram showing the functional arrangement of the multilayer substrate forming apparatus according to this example embodiment. The multilayer substrate forming apparatus according to this example embodiment is different from the second example embodiment in that it includes an accommodator and a paster. The rest of the components and operations is the same as in the second example embodiment. Hence, the same reference numerals denote the same components and operations, and a detailed description thereof will be omitted.

A multilayer substrate forming apparatus 600 includes an accommodator 601 and a paster 602. The accommodator 601 accommodates a photo-curing sheet formed in advance by a mixed material obtained by mixing a conductive material and a photo-curing resin and an insulating sheet formed in advance by an insulating resin.

Here, the photo-curing sheet is a sheet obtained by applying a mixed material onto a predetermined sheet material in various thicknesses. The insulating sheet is a sheet obtained by applying an insulating resin onto a predetermined sheet material in various thicknesses. The accommodator 601 accommodates photo-curing sheets including mixed material layers applied in various thicknesses and insulating sheets including insulating resin layers applied in various thicknesses. When the sheets to which the mixed material and the insulating resin are applied in various thicknesses are prepared in advance, an operation of applying the mixed material layer and the insulating resin layer can be omitted.

The paster 602 pastes a photo-curing sheet and an insulating sheet onto a substrate 311. The paster 602 pastes an insulating sheet after pasting a photo-curing sheet, and pastes a photo-curing sheet after pasting an insulating sheet. In this way, the paster 602 selectively pasts the photo-curing sheet and the insulating sheet. A controller 205 controls such that the paster 602 selectively pastes the photo-curing sheet and the insulating sheet.

FIG. 7 is a view showing the arrangement of the multilayer substrate forming apparatus according to this example embodiment. The multilayer substrate forming apparatus 600 includes an accommodator 701, an accommodator 702, and a paster 703. The accommodator 701 accommodates a plurality of types of photo-curing sheets 711 whose mixed material layers have different thicknesses. The accommodator 702 accommodates a plurality of types of insulating sheets 721 whose insulating resin layers have different thicknesses.

The paster 703 extracts the photo-curing sheet 711 from the accommodator 701, and pastes it onto the substrate 311. The paster 703 extracts the insulating sheet 721 from the accommodator 702, and pastes it onto the substrate 311. The paster 703 includes, for example, a switch mechanism that turns on/off static electricity. The paster 703 attracts and holds the photo-curing sheet 711 and the insulating sheet 721 by static electricity, and moves the photo-curing sheet 711 and the insulating sheet 721 to a predetermined position on the substrate 311 on a stage 301.

When the photo-curing sheet 711 and the insulating sheet 721 are moved to the predetermined position on the substrate 311, a controller 306 turns off the static electricity. When the static electricity is turned off, the photo-curing sheet 711 and the insulating sheet 721 held by the paster 703 are separated from the paster 703 and pasted onto the substrate 311.

According to this example embodiment, since the photo-curing sheet and the insulating sheet are pasted onto the substrate by the paster, the sheets can easily and quickly be pasted by the simple arrangement. In addition, since photo-curing sheets and insulating sheets of a plurality of types with different thicknesses are accommodated in the accommodators, a multilayer substrate in which circuit patterns and through holes of different thicknesses are formed in the layers can simply and quickly be obtained.

### Fourth Example Embodiment

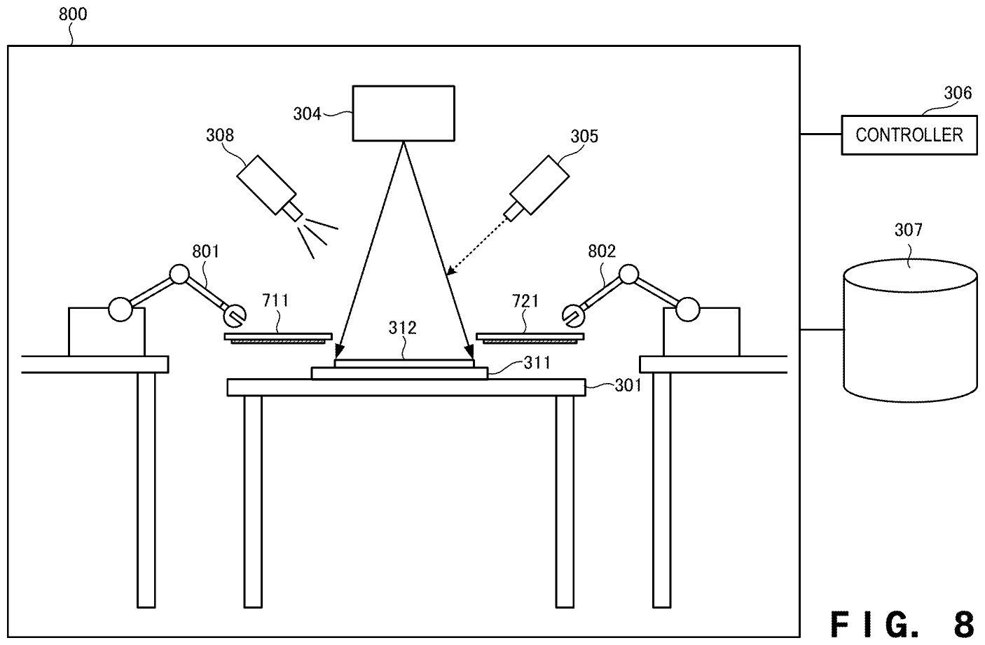

A multilayer substrate forming apparatus according to the fourth example embodiment of the present invention will be described next with reference to FIG. 8. FIG. 8 is a view showing the arrangement of the multilayer substrate forming apparatus according to this example embodiment. The multilayer substrate forming apparatus according to this example embodiment is different from the third example embodiment in that it includes arms. The rest of the components and operations is the same as in the third example embodiment. Hence, the same reference numerals denote the same components and operations, and a detailed description thereof will be omitted.

A multilayer substrate forming apparatus 800 includes arms 801 and 802. The arm 801 extracts a photo-curing sheet 711 from an accommodator (not shown), and pastes it onto a substrate 311. The arm 802 extracts an insulating sheet 721 from an accommodator (not shown), and pastes it onto the substrate 311. Photo-curing sheets and insulating sheets of a plurality of types with different thicknesses are accommodated in the accommodators.

According to this example embodiment, since the photo-curing sheet and the insulating sheet are pasted onto the substrate by the arms, the sheets can easily and quickly be pasted. In addition, since photo-curing sheets and insulating sheets of a plurality of types with different thicknesses are accommodated in the accommodators, a multilayer substrate in which circuit patterns and through holes of different thicknesses are formed in the layers can simply and quickly be obtained.

### Other Example Embodiments

Note that in the above-described example embodiments, the insulating resin used for the insulating resin layer including the through holes may be either a photo-curing resin or a photoplastic resin. In a case of a photo-curing resin, portions other than the through holes are scanned by a laser beam. In a case of a photoplastic resin, portions that become the through holes are scanned by a laser beam.

While the invention has been particularly shown and described with reference to example embodiments thereof, the invention is not limited to these example embodiments. It will be understood by those of ordinary skill in the art that various changes in form and details may be made therein without departing from the spirit and scope of the present invention as defined by the claims.

The present invention is applicable to a system including a plurality of devices or a single apparatus. The present invention is also applicable even when an information processing program for implementing the functions of example embodiments is supplied to the system or apparatus directly or from a remote site. Hence, the present invention also incorporates the program installed in a computer to implement the functions of the present invention by the computer, a medium storing the program, and a WWW (World Wide Web) server that causes a user to download the program. Especially, the present invention incorporates at least a non-transitory computer readable medium storing a program that causes a computer to execute processing steps included in the above-described example embodiments.

1. A multilayer substrate forming method comprising:
fixing a substrate on a stage;
forming, on the substrate fixed on the stage, a layer of a mixed material obtained by mixing a conductive material and a photo-curing resin;
performing exposure by scanning a laser beam according to first circuit pattern data prepared in advance on the layer of the mixed material;
washing away the mixed material on the substrate after the exposure in the performing exposure by scanning the laser beam according to the first circuit pattern data;
forming a layer of an insulating resin on the substrate after the cleaning in the washing away the mixed material on the substrate after the exposure in the performing exposure by scanning the laser beam according to the first circuit pattern data;
performing exposure by scanning a laser beam according to through hole data prepared in advance on the layer of the insulating resin;
washing away the insulating resin on the substrate after the exposure in the performing exposure by scanning the laser beam according to the through hole data;
forming a layer of the mixed material on the substrate after the cleaning in the washing away the insulating resin;
performing exposure by scanning a laser beam according to second circuit pattern data prepared in advance on the layer of the mixed material; and
washing away the mixed material on the substrate after the exposure in the performing exposure by scanning the laser beam according to the second circuit pattern data.

2. The method according to claim 1, wherein in the forming the layer of the insulating resin, the layer of the insulating resin is formed on the substrate without moving the substrate after the cleaning in the washing away the mixed material on the substrate after the exposure in the performing exposure by scanning the laser beam according to the first circuit pattern data.

3. The method according to claim 1, wherein in the forming the layer of the mixed material on the substrate after the cleaning in the washing away the insulating resin, the layer of the mixed material is formed on the substrate without moving the substrate after the cleaning in the washing away the insulating resin.

4. The method according to claim 1, wherein in the washing away the mixed material on the substrate after the exposure in the performing exposure by scanning the laser beam according to the first circuit pattern data and the washing away the mixed material on the substrate after the exposure in the performing exposure by scanning the laser beam according to the second circuit pattern data, the mixed material on the substrate after the exposure in the performing exposure by scanning the laser beam according to the first circuit pattern data and the performing exposure by scanning the laser beam according to the second circuit pattern data is washed away while keeping the substrate fixed on the stage.

5. The method according to claim 1, wherein in the washing away the insulating resin, the insulating resin on the substrate after the exposure in the performing exposure by scanning the laser beam according to the through hole data is washed away while keeping the substrate fixed on the stage.

6. The method according to claim 1, wherein each of the forming the layer of the mixed material on the substrate fixed on the stage and the forming the layer of the mixed material on the substrate after the cleaning in the washing away the insulating resin comprises pasting a photo-curing sheet formed in advance by the mixed material onto the substrate.

7. The method according to claim 1, wherein each of the forming the layer of the mixed material on the substrate fixed on the stage and the forming the layer of the mixed material on the substrate after the cleaning in the washing away the insulating resin comprises applying the mixed material onto the substrate.

8. The method according to claim 1, wherein the forming the layer of the insulating resin comprises pasting an insulating sheet formed in advance by the insulating resin onto the substrate.

9. The method according to claim 1, wherein the forming the layer of the insulating resin comprises applying the insulating resin onto the substrate.

10. The method according to claim 1, wherein the performing exposure by scanning the laser beam according to the first circuit pattern data, the performing exposure by scanning the laser beam according to the through hole data, and the performing exposure by scanning the laser beam according to the second circuit pattern data are executed using one exposure apparatus.

11. The method according to claim 1, wherein the washing away the mixed material on the substrate after the exposure in the performing exposure by scanning the laser beam according to the first circuit pattern data, the washing away the insulating resin, and the washing away the mixed material on the substrate after the exposure in the performing exposure by scanning the laser beam according to the second circuit pattern data are executed using one cleaning apparatus.

12. A multilayer substrate forming apparatus comprising:
a mixed material layer former that forms, on a substrate, a layer of a mixed material obtained by mixing a conductive material and a photo-curing resin;
an insulating resin layer former that forms a layer of an insulating resin on the substrate;
an exposurer that performs exposure;
a cleaner that performs cleaning; and
a controller that controls the mixed material layer former, the insulating resin layer former, the exposure, and the cleaner,
wherein the controller controls to perform processing of forming the layer of the mixed material by the mixed material layer former, processing of performing exposure by scanning a laser beam according to first circuit pattern data by the exposurer, processing of cleaning the mixed material after the exposure by the cleaner, processing of forming the layer of the insulating resin by the insulating resin layer former, processing of performing exposure by scanning a laser beam according to through hole data by the exposurer, and processing of cleaning the insulating resin after the exposure by the cleaner at least once, and then
perform processing of forming the layer of the mixed material by the mixed material layer former, processing of performing exposure by scanning a laser beam according to second circuit pattern data by the exposurer, and processing of cleaning the mixed material after the exposure by the cleaner.

13. The apparatus according to claim 12, wherein each of the mixed material layer former and the insulating resin layer former comprises:
an accommodator that accommodates a corresponding one of a photo-curing sheet formed in advance by the mixed material and an insulating sheet formed in advance by the insulating resin; and
a paster that pastes a corresponding one of the photo-curing sheet and the insulating sheet onto the substrate, and
the controller further controls pasting processing of the photo-curing sheet and the insulating sheet by the paster.

14. The apparatus according to claim 13, wherein the controller controls the paster to selectively paste the photo-curing sheet and the insulating sheet.

15. The apparatus according to claim 13, wherein the accommodator includes a first accommodator that accommodates the photo-curing sheet, and a second accommodator that accommodates the insulating sheet.

16. The The apparatus according to claim 13, wherein the accommodator accommodates at least one of a plurality of photo-curing sheets whose mixed material layers have different thicknesses and a plurality of insulating sheets whose insulating resin layers have different thicknesses.

17. The apparatus according to claim 16, wherein the controller controls the paster to selectively paste the plurality of photo-curing sheets having different thicknesses and the plurality of insulating sheets having different thicknesses.
